(19) United States
(12) Patent Application Publication
(10) Pub. No.: US 2008/0110486 A1
(43) Pub. Date: May 15, 2008

(54) Amorphous-crystalline tandem nanostructured solar cells

(75) Inventors: Loucas Tsakalakos, Niskayuna, NY (US); Bastiaan Arie Korevaar, Schenectady, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company, Schenectady, NY (US)

(21) Appl. No.: 11/599,677

(22) Filed: Nov. 15, 2006

(51) Int. Cl. H01L 31/042; H01L 31/00; H05H 1/24; C25D 5/00; B05D 5/12

(52) U.S. Cl. 136/244; 136/255; 427/74; 427/569; 136/248; 205/80

(57) ABSTRACT

A photovoltaic device that includes a plurality of elongated nanostructures disposed on the surface of a substrate and a multilayered film deposited conformally over the elongated nanostructures forming a plurality of photoactive junctions. A method making such a photovoltaic device includes generating a plurality of elongated nanostructures on a substrate surface and conformally depositing a multilayered film forming a plurality of photoactive junctions. The plurality of photoactive junctions are designed to capture different wavelengths of light. A solar panel includes at least one photovoltaic device.

### RELATED APPLICATIONS

This present application is related to commonly-assigned co-pending application U.S. Ser. No. 11/______, filed concurrently with this application Nov. 15, 2006, entitled “Graded Hybrid Amorphous Silicon Nanowire Solar Cells”.

### TECHNICAL FIELD

The present invention relates generally to solar cells, and more specifically to such solar cells that include stacked multi-junction arrays assembled conformally over elongated nanostructures.

### BACKGROUND INFORMATION

Presently, silicon (Si) is the most commonly used material in the fabrication of solar cells, such solar cells being used for converting sunlight into electricity. Single and multi-junction p-n solar cells are used for this purpose, but none are efficient enough to significantly reduce the costs involved in the production and use of this technology. Consequently, competition from conventional sources of electricity precludes the widespread use of such solar cell technology.

Most electronic and optoelectronic devices require the formation of a junction. For example, a material of one conductivity type is placed in contact with a different material of the opposite conductivity type to form a heterojunction. Alternatively, one may pair differentially doped layers made of a single material type to generate a p-n junction (or homojunction). Abrupt band bending at a heterojunction due to a change in conductivity type and/or variations in band gap may lead to a high density of interface states that result in charge carrier recombination. Defects introduced at the junction during fabrication may further act as sites for charge carrier recombination that degrade device performance.

Existing solar cells lose efficiency due to the fact that a photo-excited electron quickly loses any energy it may have in excess of the bandgap as a result of the interactions with lattice vibrations, known as phonons, resulting in increased recombination. This loss alone limits the conversion efficiency of a standard cell to about 44%. Additionally, recombination of photo-generated electrons and holes with trap states in the semiconductor crystal associated with point defects (interstitial impurities), metal clusters, line defects (dislocations), planar defects (stacking faults), and/or grain boundaries further reduces the efficiency. Although this latter reduction in efficiency can be overcome by using other materials with appropriate properties (particularly long diffusion lengths of the photo-generated carriers), this still does not bring this technology to a cost parity with more conventional sources of electricity.

Further loss is incurred owing to the fact that semiconductors generally will not absorb light with energy lower than the bandgap of the material used. With all of the photovoltaic losses taken into account, Shockley and Queisser were able to show that the performance of a single junction cell was limited to just over 30 percent efficiency for an optimal cell with a bandgap of 1.45 electron volts (eV) (Shockley and Queisser, “Detailed Balance Limit of Efficiency of p-n Junction Solar Cells,” J. Appl. Phys., 1961, 32(3), pp. 510-519). More recent calculations have shown this “limit efficiency” for a single junction to be 29 percent (Kerr et al., “Lifetime and efficiency of limits of crystalline silicon solar cells,” Proc. 29^{th} IEEE Photovoltaic Specialists Conference, 2002, pp. 438-441).

The absorption capacity of the materials making up a PV device may also affect the efficiency of the cell. A p-i-n thin film solar cell having an i-type semiconductor absorber layer formed of a variable bandgap material, said i-layer being positioned between a p-type semiconductor layer and an n-type semiconductor layer has been described. See U.S. Pat. No. 5,252,142. A variable bandgap i-layer absorber provides for improved photoelectric conversion efficiency.

Multi-junction solar cells have been demonstrated to have improved efficiencies as well. The improved performance may be achieved by incorporating stacked junctions with differing band gaps to capture a broader area of the light spectrum. Such devices are typically constructed with stacked p-n junctions or stacked p-i-n junctions. Each set of junctions in this array is often referred to as a cell. A typical multi-junction solar cell includes of two or three cells stacked together. The optimal bandgaps and theoretical efficiencies for multi-junction solar cells as a function of number of cells in the stack has been analyzed theoretically by Marti and Araujo (A. Marti and G. L. Araujo, Sol. Ener. Mater. Sol. Cells, 1996, 43(2), pp. 203-222)

### Nanostructures

Silicon nanowires have been described in p-n junction diode arrays (Peng et al., “Fabrication of large-Area Silicon Nanowire p-n Junction Diode Arrays,” Adv. Mater., 2004, vol. 16, pp. 73-76). Such arrays, however, were not configured for use in photovoltaic devices, nor was it suggested how such arrays might serve to increase the efficiency of solar cells.

Silicon nanostructures have been described in solar cell devices (Ji et al., “Silicon Nanostructures by Metal Induced Growth (MIG) for Solar Cell Emitters,” Proc. IEEE, 2002, pp. 1314-1317). In such devices, Si nanowires can be formed, embedded in microcrystalline Si thin films, by sputtering Si onto a nickel (Ni) pre-layer, the thickness of which determines whether the Si nanowires grow inside the film or not. However, such nanowires are not active photovoltaic (PV) elements; they merely serve in an anti-reflective capacity.

Solar cells comprising silicon nanostructures, where the nanostructures are active PV elements, have been described in commonly-assigned co-pending U.S. patent application Ser. No. 11/081,967, filed Mar. 16, 2005. In that particular Application, the charge separating junctions are largely contained within the nanostructures themselves, generally requiring doping changes during the synthesis of such nanostructures.

As a result of the foregoing, incorporating multi-junction cells over a nanostructured scaffold may lead to solar cells with efficiencies on par with the more traditional sources of electricity. Thus, there is a continuing need to explore new configurations for PV devices. This is especially the case for nanostructured devices, which may benefit from enhanced light trapping and shorter paths for charge transport upon light absorption.

### SUMMARY OF THE INVENTION

In some embodiments, a photovoltaic device includes a plurality of elongated nanostructures disposed on the surface of a substrate and a multilayered film deposited conformally over the elongated nanostructures. The multilayered film comprises a plurality of photoactive junctions. The array of photoactive junctions built over the elongated nanostructures may provide a means for capturing a broad spectrum of light. The elongated nanostructure may provide a means for creating multiple light passes to optimize light absorption.

In some embodiments, a method of making a photovoltaic device includes generating a plurality of elongated nanostructures on a substrate surface and conformally depositing a multilayered film. The multilayered film comprises a plurality of photoactive junctions.

In some embodiments, a solar panel includes at least one photovoltaic device wherein the solar panel isolates each such device from its surrounding atmospheric environment and permits the generation of electrical power.

The foregoing has outlined rather broadly the features of the present invention in order that the detailed description of the invention that follows may be better understood. Additional features and advantages of the invention will be described hereinafter, which form the subject of the claims of the invention.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a partial cross-sectional view of a photovoltaic device, in accordance with one embodiment of the present invention.

FIG. 2 shows a semiconducting nanostructure in a multi-junction device with two p-n junctions, in accordance with one embodiment of the present invention.

FIG. 3 shows a semiconducting nanostructure in a multi-junction device with three p-n junctions, in accordance with one embodiment of the present invention.

FIG. 4 shows a conducting nanostructure in a multi-junction device with two p-n junctions, in accordance with one embodiment of the present invention.

FIG. 5 shows a conducting nanostructure in a multi-junction device with two p-i-n junctions, in accordance with one embodiment of the present invention.

FIG. 6 shows the elements of the substrate on which the nanostructures are synthesized, in accordance with one embodiment of the present invention.

FIG. 7 shows the steps of a method to construct a photovoltaic device, in accordance with one embodiment of the present invention.

FIGS. 8a-c show elongated nanostructures grown on a substrate surface, in accordance with one embodiment of the present invention.

FIGS. 9a-b show a multilayered film deposited about elongated nanostructures, in accordance with one embodiment of the present invention.

### DETAILED DESCRIPTION OF THE INVENTION

In some embodiments, the present invention is directed to photovoltaic (PV) devices, which may include elongated nanostructures and a multilayered film conformally disposed on the elongated nanostructures. The multilayered film may include a plurality of photoactive junctions, such as p-n and p-i-n junctions. These photoactive junctions may be stacked with tunnel junctions separating each cell in the multi-junction array. Each cell in the multi-junction array may be arranged in series and may include p-n junctions, p-i-n junctions, and combinations thereof. In some embodiments, the elongated nanostructures may be part of a first photoactive junction and be appropriately doped as the p- or n-layer. In alternate embodiments, the elongated nanostructures may be conducting and thus, not a part of a photoactive junction.

In the following description, specific details are set forth such as specific quantities, sizes, etc. so as to provide a thorough understanding of embodiments of the present invention. However, it will be obvious to those skilled in the art that the present invention may be practiced without such specific details. In many cases, details concerning such considerations and the like have been omitted inasmuch as such details are not necessary to obtain a complete understanding of the present invention and are within the skills of persons of ordinary skill in the relevant art.

Referring to the drawings in general, it will be understood that the illustrations are for the purpose of describing a particular embodiment of the invention and are not intended to limit the invention thereto.

While most of the terms used herein will be recognizable to those of skill in the art, the following definitions are nevertheless put forth to aid in the understanding of the present invention. It should be understood, however, that when not explicitly defined, terms should be interpreted as adopting a meaning presently accepted by those of skill in the art.

A “photovoltaic device,” as defined herein, is a device comprising at least one photodiode and which utilizes the photovoltaic effect to produce an electromotive force (e.m.f.). See Penguin Dictionary of Electronics, Third Edition, V. Illingworth, Ed., Penguin Books, London, 1998. An exemplary such device is a “solar cell,” wherein a solar cell is a photodiode whose spectral response has been optimized for radiation from the sun.

“Nanoscale,” as defined herein, generally refers to dimensions below 1 μm.

“Nanostructures,” as defined herein, generally refer to structures that are nanoscale in at least two dimensions.

“Elongated nanostructures,” as defined herein, are nanostructures that are nanoscale in at least two dimensions. Exemplary such elongated nanostructures include, but are not limited to, nanowires, nanorods, nanotubes, and the like.

“Nanowires,” as defined herein, are generally elongated nanostructures typically being sub-micron (<1 μm) in at least two dimensions and having a largely cylindrical shape. They are frequently single crystals.

“Conformal,” as defined herein, pertains to coatings that largely adopt (i.e., conform to) the shape of the structures which they coat. This term should be interpreted broadly, however, permitting the substantial filling of void space between the coated structures—at least in some embodiments. A single conformal layer may vary in thickness along different sections of the structure being coated.

“Semiconducting material,” as defined herein, is material that has a conductivity that is generally intermediate between metals and insulators, and wherein such a material has an energy gap, or “bandgap,” between its valence and conduction bands. In its pure, undoped state, such semiconducting material is typically referred to as being “intrinsic.”

“p-doping,” as defined herein, refers to doping of semiconducting material with impurities that introduce holes effective for increasing the conductivity of the intrinsic semiconducting material and moving the Fermi level towards the valence band such that a junction can be formed. An exemplary such p-doping is the addition of small quantities of boron (B) to silicon (Si).

“n-doping,” as defined herein, refers to doping of semiconducting material with impurities that introduce electrons effective for increasing the conductivity of the intrinsic semiconducting material and moving the Fermi level towards the conduction band such that a junction can be formed. An exemplary such n-doping is the addition of small quantities of phosphorous (P) to silicon (Si).

A “charge separating junction,” as defined herein, comprises a boundary between materials of different type (e.g., differing dopants and/or bulk composition) that allows for the separation of electrons and holes due to the presence of a potential barrier and electric field gradient.

A “heterojunction,” as defined herein and pertaining to photovoltaic devices, is a charge separating junction established via the contact of two differing semiconductor materials having differing bandgaps.

“Active PV elements,” as defined herein, are those elements of a PV device responsible for establishing a charge-separating junction.

A “p-n photovoltaic device,” as defined herein, is a device comprising at least one photodiode comprising a charge-separating junction established via the contact of a p-doped semiconductor and an n-doped semiconductor.

A “p-i-n photovoltaic device,” as defined herein, is a stack of three materials with one layer being doped p-type (primarily hole conduction), one being undoped (i.e., intrinsic), and the other being doped n-type (primarily electron conduction).

“Multi-junction,” as defined herein, is a tandem array of stacked photoactive junctions which may include p-n and/or p-i-n junctions. Each photoactive junction may be separated from its neighboring cell by a tunnel junction.

“Solar cells,” as defined herein, is essentially a photovoltaic device for energy conversion from solar radiation.

“Nanotemplates,” as defined herein, are inorganic or organic films comprising an array of pores or columns having nanoscale dimensions. The pores generally run through the film in a substantially perpendicular direction relative to the plane of the film.

### Devices

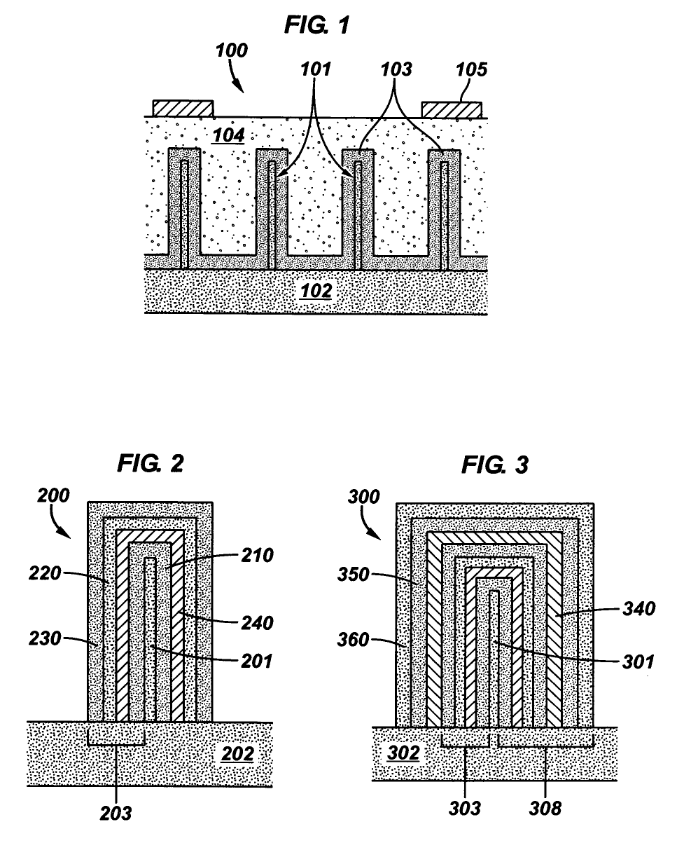

Referring to FIG. 1, in some embodiments, the present invention is directed to a multi-junction nanostructure-based photovoltaic device which may include:

(a) a plurality of elongated nanostructures 101 disposed on a substrate 102. The elongated nanostructures may include crystalline silicon nanowires, for example, and may be p-doped semiconductors, in one embodiment and n-doped semiconductors, in another embodiment. Alternatively, they may be degenerately doped silicon and other metallic material to serve as conductors; and

(b) a multilayered film 103 disposed conformally about the elongated nanostructures. At least a portion of the multilayered film 103 may form the elements of a photoactive junction, in one embodiment. In some embodiments, the photoactive junctions may be p-n junctions and, in other embodiments, they may be p-i-n junctions. In yet another embodiment, at least a portion of the multilayered film 103 may comprise a tunnel junction.

In some embodiments, a layer of transparent conductive material (TCM) 104 is deposited over the multilayered film 103. TCM 104 may substantially fill the spaces between the plurality of elongated nanostructures. Additionally, TCM 104 may form a nominally flat surface over the top of the plurality of elongated nanostructures. Furthermore, top 105 and bottom (not shown) contacts are typically provided operable for connecting the device to an external circuit, wherein the bottom electrode is typically (but not always) integrated with the substrate (vide infra).

The elongated nanostructures 101 typically have a length in the range of from about 100 nm to about 100 μm, and a width in the range of from about 5 nm to about 1 μm. In some embodiments, the nanostructures are arranged on the substrate 102 in a substantially vertical orientation, i.e., in relation to the plane of the substrate 102, a majority of said nanostructures 101 form an angle of greater than 45°. In other embodiments, the nanostructures 101 are disposed on the substrate 102 in a largely random manner.

The elongated nanostructures 101 may be of any material which suitably provides for a photovoltaic device, in accordance with various embodiments. Suitable semiconductor materials may include, but are not limited to, silicon (Si), silicon germanium (SiGe), germanium (Ge), gallium arsenide (GaAs), indium phosphide (InP), GaInP, GaInAs, indium gallium arsenide (InGaAs), indium nitride (InN), selenium (Se), cadmium telluride (CdTe), Cd—O—Te, Cd—Mn—O—Te, ZnTe, Zn—O—Te, Zn—Mn—O—Te, MnTe, Mn—O—Te, oxides of copper, carbon, Cu—In—Ga—Se, Cu—In—Se, and combinations thereof. Suitable conducting materials include, but are not limited to, degenerately doped silicon, metallic materials such as aluminum (Al), platinum (Pt), palladium (Pd), and silver (Ag), carbon nanotubes, and combinations thereof.

In some embodiments, a particular layer of the multilayered film 103 may include compositions that are p-doped and n-doped semiconductors. Non-doped layers may also be incorporated, and may include an intrinsic layer and a layer acting as a tunnel junction. In one embodiment, the multilayered film 103 may constitute cells of stacked p-n junctions. In another embodiment, the multilayered film 103 may constitute cells of stacked p-i-n junctions. In yet another embodiment, the multilayered film 103 may constitute a combination of stacked p-n and p-i-n junctions. In some embodiments, the cells may be separated by a layer serving as tunnel junction (vide infra).

The composition of portions of multilayered film 103 that constitute the photoactive junctions may be amorphous silicon (a-Si), amorphous silicon-germanium (a-SiGe), nanocrystalline silicon (nc-Si) and amorphous silicon carbide (a-SiC), for example. In one embodiment, such materials may be ordered about elongated nanostructure 101 in layers of increasing band gap energy.

Typically, the multilayered film 103 may have a thickness in the range from 5 Å to 50,000 Å. The thickness of an individual layer within multilayered film 103 may be difficult to determine, however, the thickness may be adjusted to optimize current matching between junctions of different band gap energies. That is, the thickness of a given layer may be chosen so that the photocurrents generated in each individual cell (i.e. each photoactive junction) are substantially equivalent.

In some embodiments, a particular layer of the multilayered film 103 may include a tunnel junction. In such a case, the material composition may be a metal oxide, for example zinc oxide, or a highly doped amorphous Si layer.

In some embodiments, the elongated nanostructures may be n-doped semiconductors, although they could also be p-doped. To generate a photoactive junction within the device, however, the doping of the nanostructures should be opposite that of the adjacent layer in the multilayered film. FIG. 2 shows a simple multiple p-n junction device 200 disposed on substrate 202, in accordance with one embodiment of the invention. Referring to FIG. 2, elongated nanostructure 201 may be an n-doped semiconductor, for example, and integrated as the first element of a first p-n junction (a first cell) which includes a first p-doped layer 210. A second p-n junction, may include n-doped layer 220 and p-doped layer 230, which is separated by tunnel junction 240. Each of the layers of multilayered film 203 may be deposited sequentially and conformally about the elongated nanostructure 201. One skilled in the art will recognize the benefit of varying the band gap between the two p-n junctions to capture light of varied wavelength.

Referring to FIG. 3, in another embodiment, one may add additional layers to multilayered film 303 (cf. 203, FIG. 2) deposited about elongated nanostructure 301 to create a new multilayer film 308. The additional layers may include another tunnel junction 340. Furthermore, there may be a third p-n junction including p-doped layer 350 and n-doped layer 360. In principle, any number of layers may be added to create any number of p-n-junctions with intervening tunnel junctions. The number of such stacked photoactive junctions may be dependent on the thickness that each layer introduces relative to the spacing between each of the neighboring elongated nanostructures 301 deposited on substrate 302 and by the ability to assure current matching. Thus, each photoactive junction (i.e. cell) may have component layers with a thickness that depends on the band gap energies of the materials to assure substantially equivalent photocurrents between each cell.

Further, FIG. 3 illustrates a multi-junction device having doped crystalline silicon (c-Si) as the base cell in accordance with one embodiment of the present invention. The bottom cell may include a semiconducting doped nanowire 301 and the first conformally deposited layer (cf. FIG. 2, 210) about the wire with opposite doping. The outermost (top cell), which includes layers 350 and 360 may be substantially amorphous silicon. Finally, the middle cell (cf. FIG. 2, 220/230), may be of a material with intermediate band gap energy, such as amorphous silicon germanium (a-SiGe). In another embodiment, the cells stacked from bottom to top may be c-Si, a-SiGe, and amorphous silicon carbide (a-SiC), respectively.

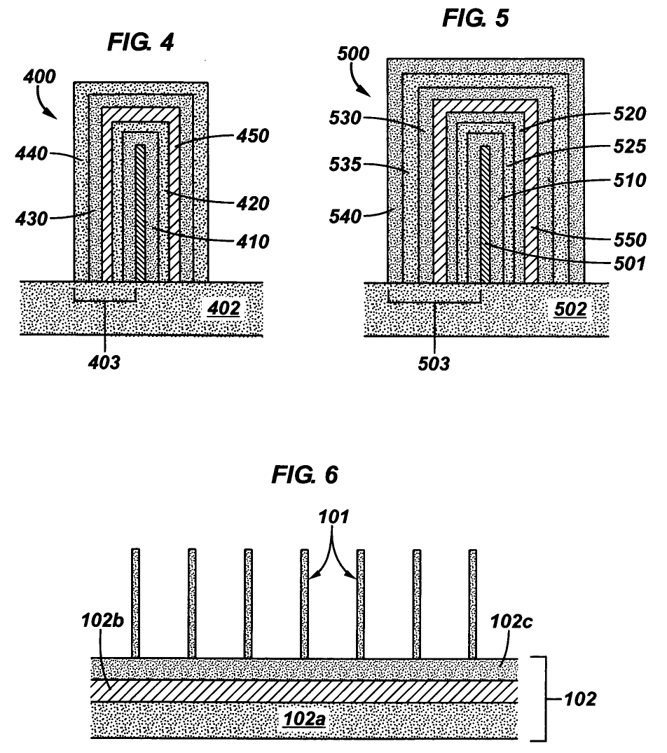

As shown in FIG. 4, the elongated nanostructure 401 of device 400 may be a conductor and not part of the stacked multi-junction structure. In this embodiment, elongated nanostructure 401 may serve as an electrode disposed on substrate 402. The multilayered film 403 may include a first p-n junction (with a first p-doped layer 410 and a first n-doped layer 420), a second p-n junction (with a second p-doped layer 430 and a second n-doped layer 440), and a tunnel junction 450 in between the first p-n junction and the second p-n junction. While this embodiment describes device 400 having two p-n junctions, one of ordinary skill in the art will recognize that three p-n junctions (with appropriate tunnel junctions interspersed) may be stacked about the elongated nanostructure 401. In additional embodiments, any number of p-n junctions may be stacked. Again spatial limitations and current matching may be limiting factors in determining the exact number of p-n junctions that may be incorporated.

For illustrative purposes, the following configurations of materials may be used in a three cell (each cell comprising a photoactive junction) device, in accordance with embodiments in which the elongated nanostructure 401 is conducting. The bottom cell (cf. FIG. 4), which includes 410 and 420, may be a-SiGe. The middle cell, which includes 430 and 440, may be a-SiGe with a different ratio of Si:Ge to obtain an intermediate band gap energy. Finally, a top cell (not shown) disposed conformally about the middle cell, may be a-Si. Another configuration of three materials, expressed from bottom cell to top cell may include, for example, nanocrystalline silicon (nc-Si), a-Si layer (intermediate band gap energy by varying hydrogen content), and a-Si. In yet another configuration, the bottom cell may be nc-Si, the middle cell a-SiGe, and top cell a-Si. One of ordinary skill in the art will recognize that any set of three materials which lend themselves to appropriate doping to generate photoactive junctions may form stacked cells. For example, each of the top cells described above may have a-SiC in lieu of a-Si as the bulk material.

As previously illustrated, the devices may have stacked p-n junctions. As shown in FIG. 5, the devices may instead include conducting elongated nanostructures 501 on substrate 502 that serve as a scaffold to conformally deposit stacked p-i-n junctions as well. Device 500 may include a multilayered film 503 that defines two stacked p-i-n junctions. The first such junction includes a first n-doped layer 510, a first intrinsic layer 525, and a first p-doped layer 520. Likewise, the second junction includes a second n-doped layer 530, a second intrinsic layer 535, and a second p-doped layer 540. The first and second p-i-n junctions are separated by tunnel junction 550. Although device 500 shows a device with 2 stacked p-i-n junctions, one of ordinary skill in the art will recognize that any number of p-i-n junctions may be stacked about the elongated nanostructure 501 within the constraints outline above.

In some embodiments, the above devices further comprise a nanoporous template residing on, or integral with, the substrate, from which the elongated semiconducting nanostructures emanate. This is often the case when such nanostructures are grown in the template. Referring to FIG. 6, in some embodiments, layered substrate 102 may comprise a nanoporous template 102c and/or a conductive layer 102b residing on a substrate support 102a.

In some embodiments, the porous nanotemplate 102c comprises a material selected from the group consisting of anodized aluminum oxide (AAO), silicon dioxide (SiO₂), boron nitride (BN), silicon nitride (Si₃N₄), and the like. In some embodiments, the porous nanotemplate 102c may have a thickness (or an average thickness) of between about 0.1 μm and about 100 μm, wherein the porous nanotemplate may have a pore diameter (or an average diameter) of between about 1 nm and about 1 μm, and wherein the porous nanotemplate may have a pore density between about 10⁵ per cm² and about 10¹² per cm².

In device embodiments employing a layer of transparent conductive material, the transparent conductive material can be a transparent conductive oxide (TCO). In some such embodiments, the transparent conductive oxide is indium-tin-oxide (ITO). In some other such embodiments, the transparent conductive oxide is doped ZnO. Typically, the transparent conductive material has a thickness between about 0.05 μM and about 1 μm.

In some embodiments, the substrate provides a bottom contact. In some embodiments, the layer of transparent conductive material provides a top contact. Depending on the intended use, the device can be configured for either top and/or bottom illumination.

### Device Fabrication

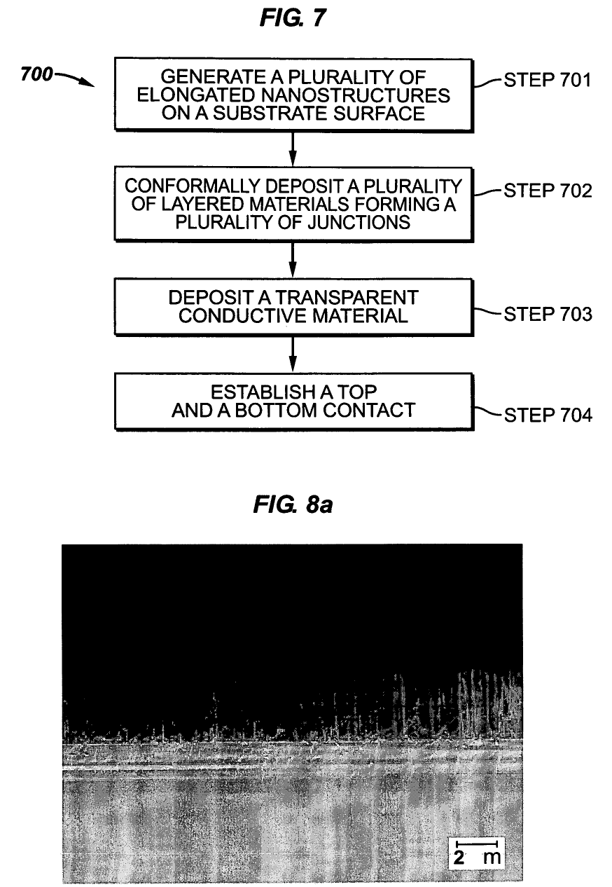

In some embodiments, the present invention is directed to a method 700 in FIG. 7 for making the above-described multi-junction nanostructure-based photovoltaic devices, in accordance with one embodiment of the present invention. Referring to FIG. 7, in conjunction with FIGS. 2-5 a plurality of elongated nanostructures is provided on a substrate in step 701. The elongated nanostructures are a semiconductor (FIGS. 2-3) in some embodiments, and a conductor (FIGS. 4-5) in other embodiments; (Step 702) a multilayered film is conformally-deposited on the elongated nanostructures, the materials of each layer having appropriate doping in some embodiments. They may also be intrinsic or serve as a tunnel junction in other embodiments; (Step 703) a conductive transparent material is deposited as a layer on the multilayer film; and (Step 704) top and bottom contacts are established, which may be operable for connection of the device to an external circuit. The top contact may be disposed on the TCM and the bottom contact may be disposed on a surface of the substrate opposite the elongated nanostructures or integrated within the substrate.

In some such above-described method embodiments, the elongated nanostructures are provided by growing them via a method selected from the group consisting of chemical vapor deposition (CVD), metal-organic chemical vapor deposition (MOCVD), plasma-enhanced chemical vapor deposition (PECVD), hot wire chemical vapor deposition (HWCVD), atomic layer deposition, electrochemical deposition, solution chemical deposition, and combinations thereof. In some such embodiments, the elongated nanostructures are provided by catalytically growing them from metal nanoparticles, where the metal nanoparticles may reside in a nanoporous template, and wherein the metal nanoparticles may include a metal selected from the group consisting of gold (Au), indium (In), gallium (Ga), and iron (Fe).

In some embodiments, a nanoporous template is employed to grow elongated nanostructures such as is described in commonly-assigned U.S. patent application Ser. No. 11/141,613, filed 27 May, 2005.

In some such above-described method embodiments, the step of conformally-depositing the multilayered film is carried out using a technique selected from the group consisting of CVD, MOCVD, PECVD, HWCVD, sputtering, and combinations thereof.

### Solar Panels

In some embodiments, the present invention is directed to a solar panel which may include at least one multi-junction nanostructure-based photovoltaic device, as disclosed herein. The solar panel isolates each devices from their surrounding atmospheric environment and permits the generation of electrical power.

Finally, embodiments of the present invention provide multi-junctioned nanostructured photovoltaic devices that may exhibit high efficiencies and may be resistant to light induced degradation. The PV cell constructed in accordance with embodiments disclosed herein may optimize absorption of light and may minimize recombination at heterojunction interfaces. Other benefits may include low cost and ease of fabrication, especially in embodiments that include a primarily silicon-based cell. Embodiments, in which the elongated nanostructures are conducting, may provide cells that are easier to current match.

### EXAMPLES

The following examples are included to demonstrate particular embodiments of the present invention. It should be appreciated by those of skill in the art that the methods disclosed in the examples that follow merely represent exemplary embodiments of the present invention. However, those of skill in the art should, in light of the present disclosure, appreciate that many changes can be made in the specific embodiments described and still obtain a like or similar result without departing from the spirit and scope of the present invention.

### Example 1

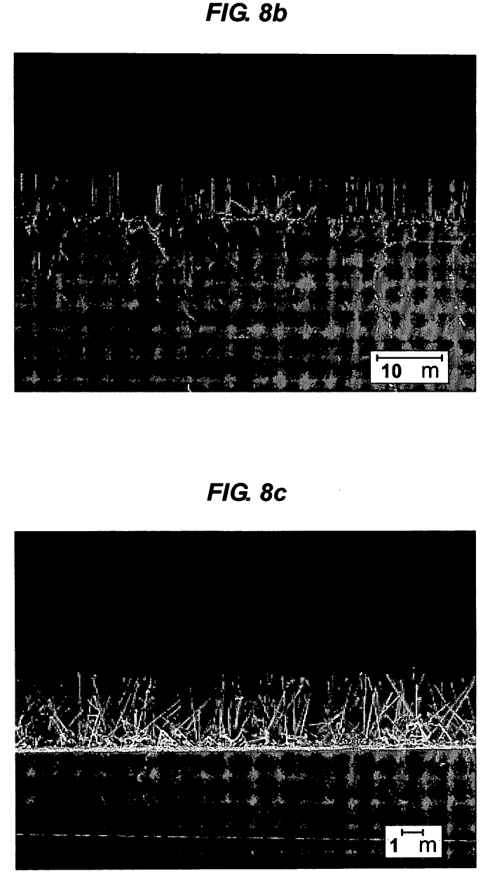

The following experimental example is included to demonstrate embodiments for the growth of nanowires as disclosed herein. They are intended to be exemplary of the present invention, and thus not limiting. FIG. 8a shows the growth of long, high density silicon nanowires having an average diameter of 57 nm. FIG. 8b, shows shorter, low density silicon nanowires having an average diameter of 182 nm. Finally, FIG. 8c demonstrates a randomized array of silicon nanowires with an average diameter of 70 nm.

### Example 2

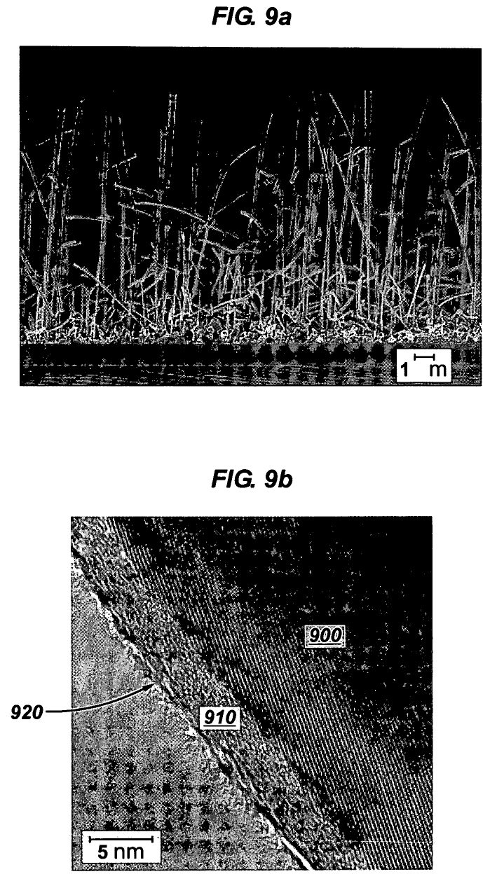

The following experimental example is included to demonstrate embodiments for the conformal deposition of layers about nanowires as disclosed herein. They are intended to be exemplary of the present invention, and thus not limiting. FIG. 9a shows high density wires with conformally deposited a-Si on long high density silicon nanowires. FIG. 9b shows a cross-sectional view of conformally deposited a-Si on a c-Si nanowire 900. The a-Si layer was introduced by CVD. The first layer of a-Si 910 is an intrinsic and the second layer 920 is n-doped.

It will be understood that certain of the above-described structures, functions, and operations of the above-described embodiments are not necessary to practice the present invention and are included in the description simply for completeness of an exemplary embodiment or embodiments. In addition, it will be understood that specific structures, functions, and operations set forth in the above-described referenced patents and publications can be practiced in conjunction with the present invention, but they are not essential to its practice. It is therefore to be understood that the invention may be practiced otherwise than as specifically described without actually departing from the spirit and scope of the present invention as defined by the appended claims.

What is claimed is:

1. A photovoltaic device comprising:
a substrate;
a plurality of elongated nanostructures disposed on a surface of the substrate of the photovoltaic device; and
a multilayered film deposited conformally over the plurality of elongated nanostructures forming a plurality of photoactive junctions.

2. The photovoltaic device of claim 1, wherein the multilayered film comprises one or more of the following: a metal oxide, amorphous silicon, amorphous silicon-germanium (SiGe), nanocrystalline silicon, and amorphous silicon carbide (SiC).

3. The photovoltaic device of claim 1, wherein the plurality of elongated nanostructures comprises silicon nanowires.

4. The photovoltaic device of claim 1, wherein a layer of the multilayered film comprises a relative thickness in the range from 5 Å to 50,000. Å.

5. The photovoltaic device of claim 4, wherein the relative thickness is chosen for current matching.

6. The photovoltaic device of claim 1, wherein the plurality of photoactive junctions comprises at least one p-n junction.

7. The photovoltaic device of claim 1, wherein the plurality of photoactive junctions comprises at least one p-i-n junction.

8. The photovoltaic device of claim 1, wherein the multilayered film further comprises at least one tunnel junction.

9. The photovoltaic device of claim 1, wherein the plurality of elongated nanostructures are integrated in a first photoactive junction.

10. The photovoltaic device of claim 1, wherein the plurality of elongated nanostructures are conductors.

11. The photovoltaic device of claim 1 further comprising;
a transparent conductive material (TCM) disposed conformally over the multilayered film in a manner such that the TCM fills spaces between each of the plurality of elongated nanostructures as well as provides a flat surface over the plurality of elongated nanostructures.

12. The photovoltaic device of claim 11 further comprising;
a top and a bottom contact operable for connecting the photovoltaic device to an external circuit;
wherein the top contact is disposed on the TCM and the bottom contact is disposed on a surface of the substrate opposite the elongated nanostructures or integrated within the substrate.

13. A method for making a photovoltaic device, the method comprising the steps of:
generating a plurality of elongated nanostructures on a substrate surface; and
conformally depositing a multilayered film over the plurality of elongated nanostructures thereby forming a plurality of photoactive junctions.

14. The method of claim 13, wherein one or more of the plurality of photoactive junctions formed comprises one or more of the following: a p-n junction, an p-i-n-junction, and a tunnel junction.

15. The method of claim 13 further comprising the step of
depositing conductive transparent material conformally over the multilayered film in a manner such that the TCM fills spaces between each of the plurality of elongated nanostructures as well as provides a flat surface over the plurality of elongated nanostructures.

16. The method of claim 13 further comprising the step of
establishing top and bottom contacts operable for connecting the photovoltaic device to an external circuit.

17. The method of claim 13, wherein the elongated nanostructures are provided by growing them via a method selected from the group consisting of CVD, MOCVD, PECVD, HWCVD, atomic layer deposition, electrochemical deposition, solution chemical deposition, and combinations thereof.

18. The method of claim 13, wherein the elongated nanostructures are provided by catalytically growing them from metal nanoparticles.

19. The method of claim 18, wherein the metal nanoparticles reside in a nanoporous template.

20. The method of claim 18, wherein the metal nanoparticles comprise a metal selected from the group consisting of gold (Au), indium (In), gallium (Ga), and iron (Fe).

21. The method of claim 13, wherein the step of conformally depositing the multilayered film is carried out using a technique selected from the group consisting of CVD, MOCVD, PECVD, HWCVD, sputtering, and combinations thereof.

22. A solar panel comprising at least one photovoltaic device of claim 1, wherein the solar panel isolates such devices from its surrounding atmospheric environment and permits the generation of electrical power.
